(19) United States
(12) Patent Application Publication
(10) Pub. No.: US 2021/0066208 A1
(43) Pub. Date: Mar. 4, 2021

(54) SEMICONDUCTOR PACKAGE AND METHOD OF MANUFACTURING THE SAME

(71) Applicant: Advanced Semiconductor Engineering, Inc., Kaohsiung (TW)

(72) Inventor: Wen-Long LU, Kaohsiung (TW)

(73) Assignee: Advanced Semiconductor Engineering, Inc., Kaohsiung (TW)

(21) Appl. No.: 16/555,667

(22) Filed: Aug. 29, 2019

(51) Int. Cl. H01L 23/00; H01L 23/31; H01L 23/538; H01L 21/48; H01L 21/56; H01L 25/065; H01L 25/00

(52) U.S. Cl. CPC H01L 23/562; H01L 2225/06586; H01L 23/5383; H01L 23/5386; H01L 23/5389; H01L 24/20; H01L 24/19; H01L 21/4857; H01L 21/4853; H01L 21/565; H01L 25/0652; H01L 25/50; H01L 2224/214; H01L 2924/3511; H01L 2924/3512; H01L 2225/0651; H01L 2225/06517; H01L 2225/06558; H01L 23/3128

(57) ABSTRACT

A semiconductor package and a method of manufacturing the same are provided. The semiconductor package includes a first dielectric layer, a first semiconductor element, a second dielectric layer, and at least one first conducive via. The first dielectric layer has a first top surface, a first bottom surface opposite to the first top surface, and a first side surface extending from the first top surface to the first bottom surface. The first semiconductor element is disposed adjacent to the first top surface of the first dielectric layer. The second dielectric layer has a second top surface, a second bottom surface opposite to the second top surface, and a second side surface extending from the second top surface to the second bottom surface, where the second dielectric layer covers a top surface of the first semiconductor element and the first side surface of the first dielectric layer. The first conductive via extends from the first top surface of the first dielectric layer to the second top surface of the second dielectric layer.

### BACKGROUND

### 1. Technical Field

The present disclosure relates to a semiconductor package and a method of manufacturing the same and, more particularly, to a semiconductor package including at least one embedded semiconductor element.

### 2. Description of the Related Art

There is a continuing desire to incorporate more than one semiconductor component into a single semiconductor package to reduce dimensions of the package. Because semiconductor components in a semiconductor package specify electrical connections to the external environment and because they may have different sizes and different coefficients of thermal expansion (CTE), warpage or cracking may occur in a semiconductor package incorporating multiple semiconductor components. It would be therefore desirable to provide semiconductor packages that can ease warpage or cracking problem, where the semiconductor components can function properly or can achieve the specified performances and at the same time satisfy the miniaturization demand.

### SUMMARY

In an aspect, a semiconductor package includes a first dielectric layer, a first semiconductor element, a second dielectric layer, and at least one first conducive via. The first dielectric layer has a first top surface, a first bottom surface opposite to the first top surface, and a first side surface extending from the first top surface to the first bottom surface. The first semiconductor element is disposed adjacent to the first top surface of the first dielectric layer. The second dielectric layer has a second top surface, a second bottom surface opposite to the second top surface, and a second side surface extending from the second top surface to the second bottom surface, where the second dielectric layer covers a top surface of the first semiconductor element and the first side surface of the first dielectric layer. The first conductive via extends from the first top surface of the first dielectric layer to the second top surface of the second dielectric layer.

In an aspect, a substrate includes a first dielectric layer, a first semiconductor element, a first bonding pad, a second dielectric layer, and at least one first conducive via. The first dielectric layer has a first top surface, a first bottom surface opposite to the first top surface, and a first side surface extending from the first top surface to the first bottom surface. The first semiconductor element is disposed adjacent to the first top surface of the first dielectric layer. The first bonding pad is disposed adjacent to the first top surface of the first dielectric layer, where the first semiconductor element electrically connects to the first bonding pad. The second dielectric layer has a second top surface, a second bottom surface opposite to the second top surface, and a second side surface extending from the second top surface to the second bottom surface, where the second dielectric layer encapsulates the first semiconductor element and exposes the first bottom surface of the first dielectric layer. The first conductive via extends from the first top surface of the first dielectric layer to the second top surface of the second dielectric layer.

In an aspect, a method of manufacturing a semiconductor package includes: providing a first dielectric layer having a first top surface, a first bottom surface opposite to the first top surface, and a first side surface extending from the first top surface to the first bottom surface; disposing a first semiconductor element adjacent to the first top surface of the first dielectric layer; and disposing a second dielectric layer having a second top surface, a second bottom surface opposite to the second top surface, and a second side surface extending from the second top surface to the second bottom surface to cover the top surface of the first semiconductor element and the first side surface of the first dielectric layer.

### BRIEF DESCRIPTION OF THE DRAWINGS

FIG. 1 illustrates a cross-sectional view of a semiconductor package according to an embodiment of the present disclosure.

FIG. 2 illustrates an enlarged view of a region of the semiconductor package illustrated in FIG. 1.

FIG. 3 illustrates a cross-sectional view of a semiconductor package according to an embodiment of the present disclosure.

FIG. 4 illustrates a cross-sectional view of a semiconductor package according to an embodiment of the present disclosure.

FIG. 5 illustrates an enlarged view of a region of the semiconductor package illustrated in FIG. 4.

FIG. 6 illustrates a cross-sectional view of a semiconductor package according to an embodiment of the present disclosure.

FIG. 7 illustrates a cross-sectional view of a semiconductor package according to an embodiment of the present disclosure.

FIG. 8 illustrates a cross-sectional view of a semiconductor package according to an embodiment of the present disclosure.

FIG. 9A, FIG. 9B, FIG. 9C, FIG. 9D, FIG. 9E, FIG. 9F, FIG. 9G, FIG. 9H, and FIG. 9I illustrate a method for manufacturing a semiconductor package such as the semiconductor package of FIG. 1.

FIG. 9A, FIG. 9B, FIG. 9C, FIG. 9D, FIG. 9E, FIG. 9F, FIG. 9G, FIG. 9H, FIG. 9I, FIG. 9J, and FIG. 9K illustrate a method for manufacturing a semiconductor package such as the semiconductor package of FIG. 3.

FIG. 9A, FIG. 9B, FIG. 9C, FIG. 9D, FIG. 9E, FIG. 9F, FIG. 9G, FIG. 9H, FIG. 9I, FIG. 9J, FIG. 9K, and FIG. 9L illustrate a method for manufacturing a semiconductor package such as the semiconductor package of FIG. 4.

FIG. 9A, FIG. 9B, FIG. 9C, FIG. 9D, FIG. 9E, FIG. 9F, FIG. 9G, FIG. 9H, FIG. 9I, FIG. 9J, FIG. 9K, FIG. 9L, and FIG. 9M illustrate a method for manufacturing a semiconductor package according to an embodiment of the present disclosure.

### DETAILED DESCRIPTION

Spatial descriptions, such as “above,” “top,” and “bottom” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

In some embodiments, the present disclosure provides for an improved semiconductor package including at least one embedded semiconductor element that can allow the embedded semiconductor element to accommodate more interconnections, while the semiconductor element can function properly or can achieve the specified performances and at the same time satisfy the miniaturization demand.

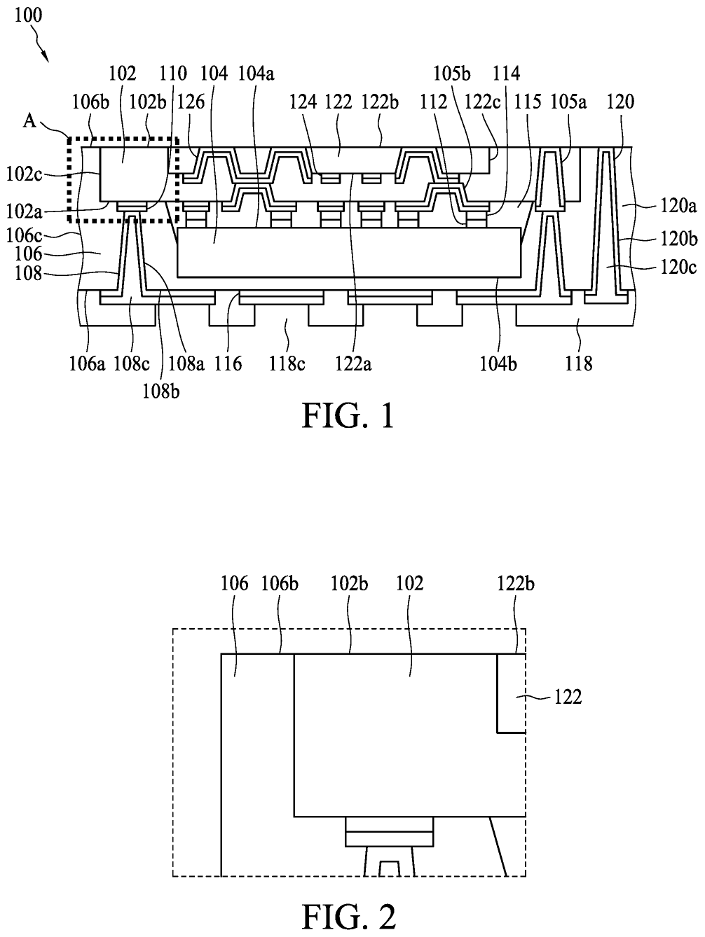

FIG. 1 illustrates a cross-sectional view of a semiconductor package 100 according to an embodiment of the present disclosure. The semiconductor package 100 of FIG. 1 includes a first dielectric layer 102, a first semiconductor element 104, a second dielectric layer 106, and at least one first conducive via 108.

The first dielectric layer 102 has a first top surface 102a, a first bottom surface 102b opposite to the first top surface 102a, and a first side surface 102c extending from the first top surface 102a to the first bottom surface 102b. The first dielectric layer 102 may include at least one first bonding pad 110 disposed adjacent to the first top surface 102a of the first dielectric layer 102, at least one second conductive via 105a extending from the first top surface 102a of the first dielectric layer 102 to the first bottom surface 102a of the first dielectric layer 102, and at least one third conductive via 105b extending from the first top surface 102a of the first dielectric layer 102 but ending before the first bottom surface 102a of the first dielectric layer 102. In some embodiments, the first bonding pad 110 is disposed directly (e.g., in physical contact) on the first top surface 102a of the first dielectric layer 102 and the second conductive via 105a is a through-layer conductive via. The first dielectric layer 102 may include a photosensitive material (e.g., polypropylene (PP)), fiber, or a combination thereof. In some embodiments, the first dielectric layer 102 includes PP and fiber. The first bonding pad 110 may be, for example, a contact pad of a trace. The first bonding pad 110 may include, for example, one of, or a combination of, copper, gold, indium, tin, silver, palladium, osmium, iridium, ruthenium, titanium, magnesium, aluminum, cobalt, nickel, or zinc, or other metals or metal alloys.

The first semiconductor element 104 may be a die, a chip, a package, an interposer, or a combination thereof. The first semiconductor element 104 has a first element top surface 104a and a first element bottom surface 104b opposite to the first element top surface 104a. The first semiconductor element 104 is disposed adjacent to the first top surface 102a of the first dielectric layer 102. The first semiconductor element 104 may be electrically connected to the first top surface 102a of the first dielectric layer 102. Alternatively, the first semiconductor element 104 may be insulated connected to the first top surface 102a of the first dielectric layer 102. The first semiconductor element 104 may include at least one first element bonding pad 112 disposed adjacent to the first element top surface 104a of the first semiconductor element 104. In some embodiments, the first element bonding pad 112 is disposed directly (e.g., in physical contact) on the first element top surface 104a of the first semiconductor element 104. The first element bonding pad 112 may include, for example, one of, or a combination of, copper, gold, indium, tin, silver, palladium, osmium, iridium, ruthenium, titanium, magnesium, aluminum, cobalt, nickel, or zinc, or other metals or metal alloys.

A first conductive connector 114 may be disposed on the first bonding pad 110 or the first element bonding pad 112. The first conductive connector 114 may be, for example, a pillar structure, which may include an under bump metallization (UBM) layer, a pillar, a barrier layer, a solder layer, or a combination of two or more thereof.

In some embodiments, the first bonding pad 110 is disposed on the first top surface 102a of the first dielectric layer 102, the first element bonding pad 112 is disposed on the first element surface 104a of the first semiconductor element 104, the first conductive connector 114 is disposed on the first element bonding pad 112, and the first semiconductor element 104 electrically connects to the first top surface 102a of the first dielectric layer 102 through the first bonding pad 110, the first element bonding pad 112, and the first conductive connector 114.

The second dielectric layer 106 has a second top surface 106a, a second bottom surface 106b opposite to the second top surface 106a, and a second side surface 106c extending from the second top surface 106a to the second bottom surface 106b. The second dielectric layer 106 is disposed adjacent to the first top surface 102a of the first dielectric layer 102. In some embodiments, the second dielectric layer 106 covers a portion of the first top surface 102a of the first dielectric layer 102 and at least a portion of the first side surface 102c of the first dielectric layer 102. In some embodiments, the second dielectric layer 106 covers a portion of the first top surface 102a of the first dielectric layer 102, at least a portion of the first side surface 102c of the first dielectric layer 102, and at least a portion of the first element bottom surface 104b of the first semiconductor element 104. In some embodiments, the second bottom surface 106b of the second dielectric layer 106 is in substantially the same plane with the first bottom surface 102b of the first dielectric layer 102. In some embodiments where the second dielectric layer 106 covers the entire side surface 102c of the first dielectric layer 102 and the entire first element bottom surface 104b of the first semiconductor element 104 but exposes at least a portion of the first bottom surface 102b of the first dielectric layer 102, the semiconductor package 100 including the first dielectric layer 102, the first semiconductor element 104, the second dielectric layer 106, and at least one first conducive via 108 may be considered a substrate (or an embedded substrate).

The second dielectric layer 106 may include at least one second bonding pad 116 disposed adjacent to the second top surface 106a of the second dielectric layer 106. In some embodiments, the second bonding pad 116 is disposed directly (e.g., in physical contact) on the second top surface 106a of the second dielectric layer 106. The second dielectric layer 106 may include a photosensitive material (e.g., polypropylene (PP)), fiber, or a combination thereof. In some embodiments, the first dielectric layer 102 includes PP and fiber.

The material of the first dielectric layer 102 and the material of the second dielectric layer 106 may be selected depending on the desired coefficient of thermal expansion (CTE). In some embodiments, the material of the first dielectric layer 102 and the material of the second dielectric layer 106 are selected so that the second dielectric layer 106 has a CTE higher than that of the first dielectric layer 102. By designing the second dielectric layer 106 as having a CTE higher than that of the first dielectric layer 102, the second dielectric layer 106 may expand toward the first dielectric layer 102, resulting in a thermal stress in an opposed direction to the thermal stress produced by the first semiconductor element 104. Therefore, the warpage of the semiconductor package 100 caused by the thermal stress of the first semiconductor element 104 can be eased.

The first conductive via 108 may extend from the first top surface 102a of the first dielectric layer 102 to the second top surface 106a of the second dielectric layer 106. In some embodiments, the first conductive via 108 electrically connects to the first bonding pad 110 disposed adjacent to the first top surface 102a of the first dielectric layer 102. In some embodiments, the first conductive via 108 electrically connects to the second bonding pad 116 disposed adjacent to the second top surface 106a of the second dielectric layer 106. In some embodiments, the first conductive via 108 electrically connects the first bonding pad 110 to the second bonding pad 116. The first conductive via 108 may include a first via 108a, a first conductive layer 108b, and a first conductive layer 108c. The first conductive layer 108b may be, for example, a metal seed layer. The first conductive layer 108c may be, for example, a metal layer.

In some embodiments, such as the one illustrated in FIG. 1, the semiconductor package 100 may further include an underfill 115 disposed between the first dielectric layer 102 and the first semiconductor element 104 to protect the first conductive connector 114 from oxidation, moisture, and other environment conditions to meet the packaging application specifications.

In some embodiments, such as the one illustrated in FIG. 1, the semiconductor package 100 may further include a protective layer 118 disposed adjacent to the second top surface 106a of the second dielectric layer 106. In some embodiments, the protective layer 118 is disposed on the second top surface 106a of the second dielectric layer 106. The protective layer 118 defines at least one first opening 118c. Each first opening 118c may correspond to a respective second bonding pad 116 and expose a portion of the second bonding pad 116. In some embodiments, the protective layer 118 covers a portion of the second bonding pad 116 and a portion of the second top surface 106a of the second dielectric layer 106. The protective layer 118 may include polyamide or other suitable materials (e.g., photosensitive materials). The protective layer 118 may be a passivation layer or an insulation layer (the material of which may be silicon oxide or silicon nitride, or another insulation material).

In some embodiments, such as the one illustrated in FIG. 1, the semiconductor package 100 may further include a fourth conductive via 120 extending from the second bottom surface 106b of the second dielectric layer 106 to the second top surface 106a of the second dielectric layer 106. In some embodiments, the fourth conductive via 120 electrically connects to the second bonding pad 116 disposed adjacent to the second top surface 106a of the second dielectric layer 106. The fourth conductive via 120 may include a fourth via 120a, a fourth conductive layer 120b, and a fourth conductive layer 120c. The fourth conductive layer 120b may be, for example, a metal seed layer. The fourth conductive layer 120c may be, for example, a metal layer.

In some embodiments, such as the one illustrated in FIG. 1, the first dielectric layer 102 may be further disposed adjacent to a third dielectric layer 122. The third dielectric layer 122 has a third top surface 122a, a third bottom surface 122b opposite to the third top surface 122a, and a third side surface 122c extending from the third top surface 122a to the third bottom surface 122b. In some embodiments, the first dielectric layer 102 covers the third top surface 122a and the third side surface 122c of the third dielectric layer 122. In some embodiments, the first dielectric layer 102 surrounds the third dielectric layer 122 and exposes the third bottom surface 122b of the third dielectric layer 122. In some embodiments, the third bottom surface 122b of the third dielectric layer 122 is in substantially the same plane with the first bottom surface 102b of the first dielectric layer 102. In some embodiments, the third bottom surface 122b of the third dielectric layer 122 is in substantially the same plane with the second bottom surface 106b of the second dielectric layer 106. In some embodiments, the third bottom surface 122b of the third dielectric layer 122 is in substantially the same plane with the first bottom surface 102b of the first dielectric layer 102 and the second bottom surface 106b of the second dielectric layer 106.

The third dielectric layer 122 may include at least one trace layer 124 disposed adjacent to the third top surface 122a of the third dielectric layer 122.

The third dielectric layer 122 may include at least one fifth conductive via 126 extending from the third top surface 122a of the third dielectric layer 122 to the third bottom surface 122b of the third dielectric layer 122 so that it can be further electrically connected to another semiconductor element through the fifth conductive via 126. The fifth conductive via 126 may electrically connect to the third conductive via 105b of the first dielectric layer 102. In some embodiments, the fifth conductive via 126 electrically connects to the third conductive via 105b of the first dielectric layer 102 and the third conductive via 105b of the first dielectric layer 102 electrically connects to the first semiconductor element 104. The fifth conductive via 126 may be a through-layer conductive via. The third dielectric layer 122 may be, for example, formed of a photosensitive material or other suitable materials (such as polyamide (PA)).

FIG. 2 illustrates an enlarged view of a region A of the semiconductor package 100 illustrated in FIG. 1. In some embodiments, such as the one illustrated in FIG. 2, the second bottom surface 106b of the second dielectric layer 106 is in substantially the same plane with the first bottom surface 102b of the first dielectric layer 102. In some embodiments, such as the one illustrated in FIG. 2, the third bottom surface 122b of the third dielectric layer 122 is in substantially the same plane with the second bottom surface 106b of the second dielectric layer 106. In some embodiments, the second bottom surface 106b of the second dielectric layer 106 is in substantially the same plane with the first bottom surface 102b of the first dielectric layer 102 and the third bottom surface 122b of the third dielectric layer 122. In some embodiments, such as the one illustrated in FIG. 2, the second dielectric layer 106 has a projective surface area greater than that of the first dielectric layer 102. In some embodiments, such as the one illustrated in FIG. 2, the first dielectric layer 102 has a projective surface area greater than that of the third dielectric layer 122. In some embodiments, such as the one illustrated in FIG. 2, the second dielectric layer 106 has a projective surface area greater than that of the first dielectric layer 102 and that of the third dielectric layer 122. By disposing a second dielectric layer 106 having a projective surface area greater than that of the first dielectric layer 102 or the first dielectric layer 102 having a projective surface area greater than that of the third dielectric layer 122, the warpage caused by the thermal stress from the semiconductor element 104 may be eased as the first dielectric layer 102 may hold the third dielectric layer 122 and the second dielectric layer 106 may hold the first dielectric layer 102, which may provide resistance against the thermal stress from the semiconductor element 104.

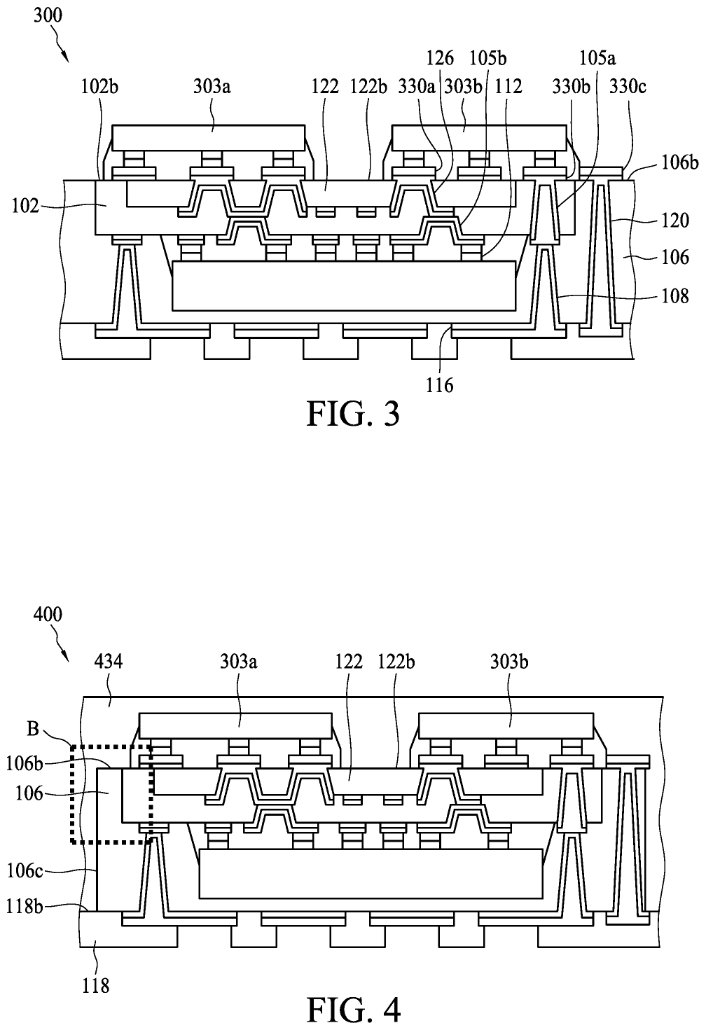

FIG. 3 illustrates a cross-sectional view of a semiconductor package 300 according to an embodiment of the present disclosure. The semiconductor package 300 is similar to that illustrated in FIG. 1, with a difference including that a third bonding pad 330a, 330b, 330c and at least one second semiconductor element 303a, 303b are disposed adjacent to the first bottom surface 102b of the first dielectric layer 102, the second bottom surface 106b of the second dielectric layer 106, or the third bottom surface 122b of the third dielectric layer 122. The third bonding pad 330a, 330b, 330c may electrically connect to the first bottom surface 102b of the first dielectric layer 102, the second bottom surface 106b of the second dielectric layer 106, or the third bottom surface 122b of the third dielectric layer 122. The second semiconductor element 303a, 303b may electrically connect to the third bonding pad 330a, 330b, 330c.

The second semiconductor element 303a, 303b may be a die, a chip, a package, an interposer, or a combination thereof.

In some embodiments, the third bonding pad 330a electrically connects to the fifth conductive via 126 exposed from the third bottom surface 122b of the third dielectric layer 122. In some embodiments where the third bonding pad 330a electrically connects to the fifth conductive via 126, the fifth conductive via 126 electrically connects to the third conductive via 105b, the third conductive via 105b electrically connects to the first element bonding pad 112 of the first semiconductor element 104, the second semiconductor element 303a, 303b disposed adjacent to the first bottom surface 102b of the first dielectric layer 102 can electrically connect to the first semiconductor element 104 disposed adjacent to the first top surface 102a of the first dielectric layer 102 (e.g., a semiconductor element disposed adjacent to one side of the first dielectric layer 102 can be electrically connected to another semiconductor element disposed adjacent to the other side of it).

In some embodiments, the third bonding pad 330b electrically connects to the second conductive via 105a of the first dielectric layer 102. In some embodiments, the second conductive via 105a electrically connects to the first conductive via 108 of the second dielectric layer 106. In some embodiments, the first conductive via 108 electrically connects to the second bonding pad 116. In some embodiments where the third bonding pad 330b electrically connects to the second conductive via 105a of the first dielectric layer 102, the second conductive via 105a electrically connects to the first conductive via 108 of the second dielectric layer 106, the first conductive via 108 electrically connects to the second bonding pad 116, an electrical signal can be transmitted from the first bottom surface 102b of the first dielectric layer 102 to the second top surface 106a of the second dielectric layer 106.

In some embodiments, the third bonding pad 330c electrically connects to the fourth conductive via 120 of the second dielectric layer 106. In some embodiments, the fourth conductive via 120 electrically connects to the second bonding pad 116 of the second dielectric layer 106. In some embodiments where the third bonding pad 330c electrically connects to the fourth conductive via 120 of the second dielectric layer 106 and the fourth conductive via 120 electrically connects to the second bonding pad 116 of the second dielectric layer 106, an electrical signal can be transmitted from one side of the second dielectric layer 106 to the other side of the second dielectric layer 106 (e.g., from the second bottom surface 106b of the second dielectric layer 106 to the second top surface 106a of the second dielectric layer 106).

FIG. 4 illustrates a cross-sectional view of a semiconductor package 400 according to an embodiment of the present disclosure. The semiconductor package 400 is similar to that illustrated in FIG. 3, with a difference including that a fourth dielectric layer 434 is disposed adjacent to the second bottom surface 106b of the second dielectric layer 106. In some embodiments, the fourth dielectric layer 434 covers a portion of the second bottom surface 106b of the second dielectric layer 106 and at least a portion of the second side surface 106c of the second dielectric layer 106. In some embodiments, the fourth dielectric layer 434 covers a portion of the second bottom surface 106b of the second dielectric layer 106, at least a portion of the second side surface 106c of the second dielectric layer 106, and a portion of the surface 118b of the protective layer 118. In some embodiments, the fourth dielectric layer 434 covers the second semiconductor element 303a, 303b. In some embodiments, the fourth dielectric layer 434 surrounds the second semiconductor element 303a, 303b and the second dielectric layer 106. In some embodiments, the fourth dielectric layer 434 encapsulates the second semiconductor element 303a, 303b and the second dielectric layer 106. In some embodiments, the fourth dielectric layer 434 encapsulates the second semiconductor element 303a, 303b and surrounds the second dielectric layer 106.

The material of the fourth dielectric layer 434 may be selected depending on the desired CTE. In some embodiments, the material of the fourth dielectric layer 434 is selected so that the fourth dielectric layer 434 has a CTE higher than that of the second dielectric layer 106. As described above, by designing an outer dielectric layer as having a CTE higher than that of the inner one, the warpage of the semiconductor package 100 caused by the thermal stress of the first semiconductor element 104 can be eased by providing a thermal stress in a direction opposed to the thermal stress caused by the first semiconductor element 104.

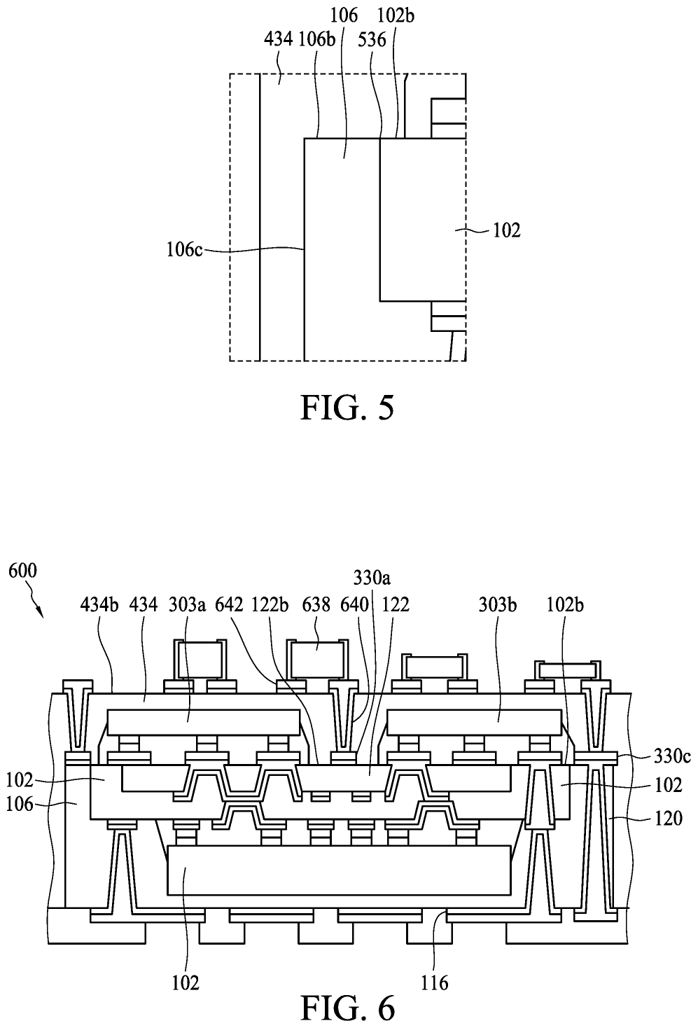

FIG. 5 illustrates an enlarged view of a region B of the semiconductor package 400 illustrated in FIG. 4. In addition to a portion of the second side surface 106c of the second dielectric layer 106, the fourth dielectric layer 434 may cover a portion of the second bottom surface 106b of the second dielectric layer 106, a portion of the first bottom surface 102b of the first dielectric layer 102, and/or a portion of the third bottom surface 122b of the third dielectric layer 122 (shown in FIG. 4). In some embodiments, the fourth dielectric layer 434 further covers a portion of the second bottom surface 106b of the second dielectric layer 106. In some embodiments, the fourth dielectric layer 434 further covers a portion of the second bottom surface 106b of the second dielectric layer 106 and a portion of the first bottom surface 102b of the first dielectric layer 102. In some embodiments, the fourth dielectric layer 434 further covers a portion of the second bottom surface 106b of the second dielectric layer 106, a portion of the first bottom surface 102b of the first dielectric layer 102, and a portion of the third bottom surface 122b of the third dielectric layer 122. By disposing a fourth dielectric layer 434 covering a portion of the second side surface 106c of the second dielectric layer 106 and a portion of the second bottom surface 106b of the second dielectric layer 106, a portion of the first bottom surface 102b of the first dielectric layer 102, and/or a portion of the third bottom surface 122b of the third dielectric layer 122, the fourth dielectric layer 434 can provide a holding effect to the second dielectric layer 106, which can further reduce the warpage caused by the thermal stress of the first semiconductor element 104.

In some embodiments, such as the one illustrated in FIG. 5, the fourth dielectric layer 434 has a projective surface area greater than that of the second dielectric layer 106. As described above, by disposing an outer dielectric layer having a projective surface area greater than that of an inner one, the warpage caused by the thermal stress from the semiconductor element 104 may be eased as the outer dielectric layer 434 may hold the inner dielectric layer 106, which may provide resistance against the thermal stress from the semiconductor element 104.

In addition, since the bonding interface between the first dielectric layer 102 and the second dielectric layer 106 are not exposed (e.g., the bonding interface 536 between the first bottom surface 102b of the first dielectric layer 102 and the second bottom surface 106b of the second dielectric layer 106 is covered by the fourth dielectric layer 434), a breakage typically occurred at the bonding interface between the first dielectric layer 102 and the second dielectric layer 106 (e.g., the bonding interface 536 between the first bottom surface 102b of the first dielectric layer 102) may be reduced, which can improve the reliability of the package.

FIG. 6 illustrates a cross-sectional view of a semiconductor package 600 according to an embodiment of the present disclosure. The semiconductor package 600 is similar to that illustrated in FIG. 4, with a difference including that at least one electronic component 638 and at least one fourth bonding pad 642 are disposed adjacent to the fourth bottom surface 434b of the fourth dielectric layer 434, and a sixth conductive via 640 is disposed in the fourth dielectric layer 434.

The electronic component 638 may be a resistor, a capacitor, an inductor, or a combination thereof. In some embodiments, the electronic component 638 electrically connects to the fourth dielectric layer 434. In some embodiments, the electronic component 638 electrically connects to the fourth dielectric layer 434 through the fourth bonding pad 642.

The fourth bonding pad 642 may electrically connect to the first dielectric layer 102, the second dielectric layer 106, or the third dielectric layer 122. The fourth bonding pad 642 may be, for example, a contact pad of a trace. The fourth bonding pad 642 may include, for example, one of, or a combination of, copper, gold, indium, tin, silver, palladium, osmium, iridium, ruthenium, titanium, magnesium, aluminum, cobalt, nickel, or zinc, or other metals or metal alloys.

The sixth conductive via 640 may extend from the fourth bottom surface 434b of the fourth dielectric layer 434 to the third bottom surface 122b of the third dielectric layer 122, to the fourth top surface 434a of the fourth dielectric layer 434, to the first bottom surface 102b of the first electric layer 102, to the second bottom surface 106b of the second dielectric layer 106, or to the third bottom surface 122b of the third dielectric layer 122.

In some embodiments where the electronic component 638 electrically connects to the fourth bonding pad 642, the fourth bonding pad 642 electrically connects to the sixth conductive via 640, the sixth conductive via 640 electrically connects to the third bonding pad 330c, the third bonding pad 330c electrically connects to the fourth conductive via 120, and the fourth conductive via 120 electrically connects to the second bonding pad 116 of the second dielectric layer 106, the electronic component 638 may be electrically connected to a semiconductor element disposed adjacent to the other side of the fourth dielectric layer 434 (e.g., electrically connected to a semiconductor element disposed adjacent to the second top surface 106a of the second dielectric layer 106).

In some embodiments where the electronic component 638 electrically connects to the fourth bonding pad 642, the fourth bonding pad 642 electrically connects to the sixth conductive via 640, the sixth conductive via 640 electrically connects to the third bonding pad 330a disposed adjacent to the third bottom surface 122b of the third dielectric layer 122, the electronic component 638 may be electrically connected to a semiconductor element disposed in the fourth dielectric layer 434 through the third dielectric layer 122 (e.g., the first semiconductor element 102 above the first dielectric layer 102 or the second semiconductor element 303a, 303b below the first dielectric layer 102).

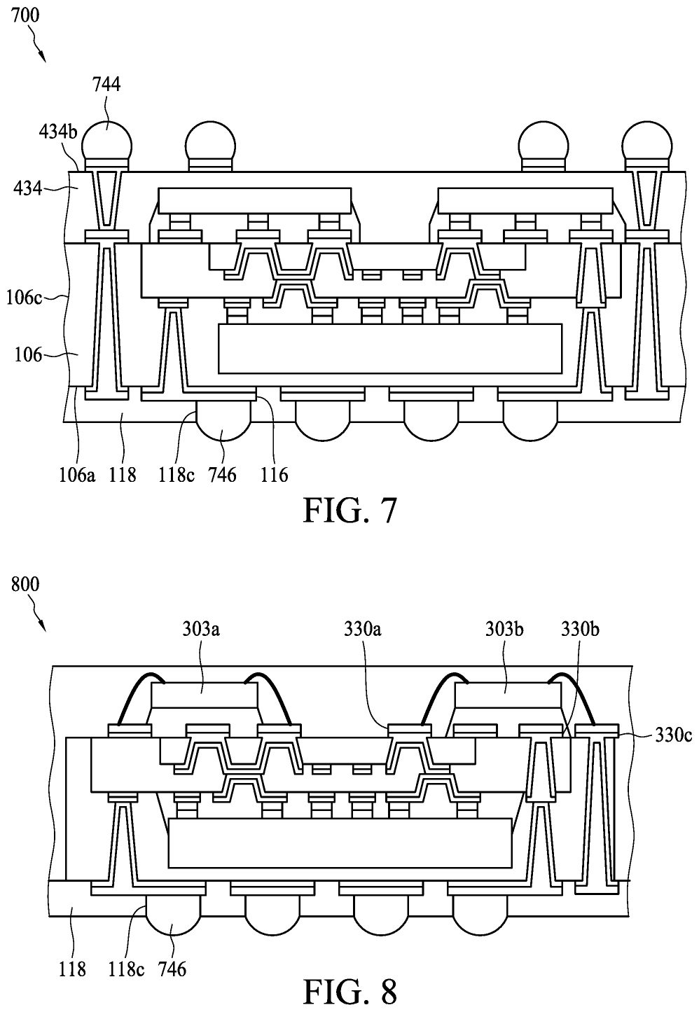

FIG. 7 illustrates a cross-sectional view of a semiconductor package 700 according to an embodiment of the present disclosure. The semiconductor package 700 is similar to that illustrated in FIG. 6, with a difference including that at least one second electrical connector 744 is disposed adjacent to the fourth bottom surface 434b of the fourth dielectric layer 434, at least one third electrical connector 746 is disposed adjacent to the opening 118c defined by the protective layer 118, and the fourth dielectric layer 434 does not cover the second side surface 106c of the second dielectric layer 106. In some embodiments, the second electrical connector 744 electrically connects to the fourth bonding pad 642 and the third electrical connector 746 electrically connects to the exposed portion of the second bonding pad 116 so that an electrical signal may be transmitted from one side of the package to the other side of the package (e.g., from the fourth bottom surface 434b of the fourth dielectric layer 434 to the second top surface 106a of the second dielectric layer 106). The second electrical connector 744 and the external electrical connector 746 may be a pillar or a solder/stud bump.

FIG. 8 illustrates a cross-sectional view of a semiconductor package 800 according to an embodiment of the present disclosure. The semiconductor package 800 is similar to that illustrated in FIG. 4, with a difference including that at least one third electrical connector 746 is disposed adjacent to the opening 118c defined by the protective layer 118, and the second semiconductor element 303a, 303b electrically connects to the third bonding pad 330a, 330b, 330c by wire bonding.

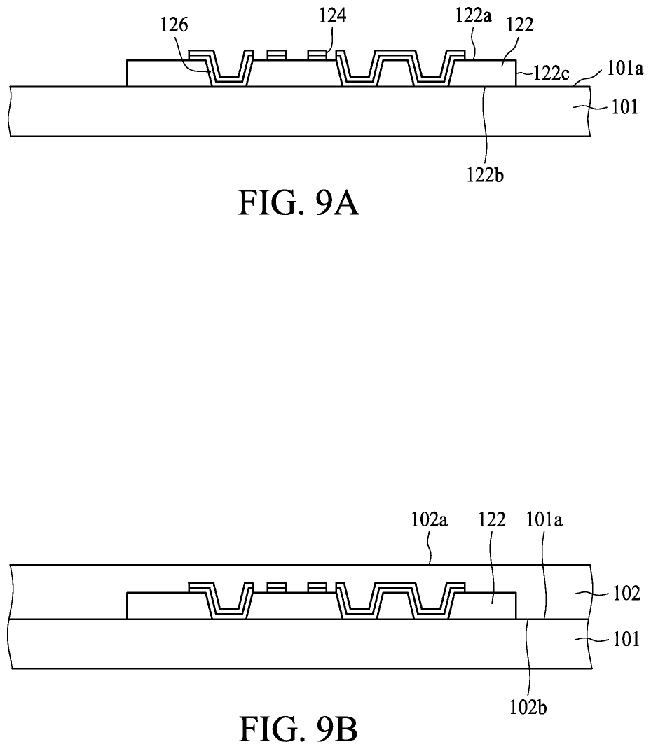

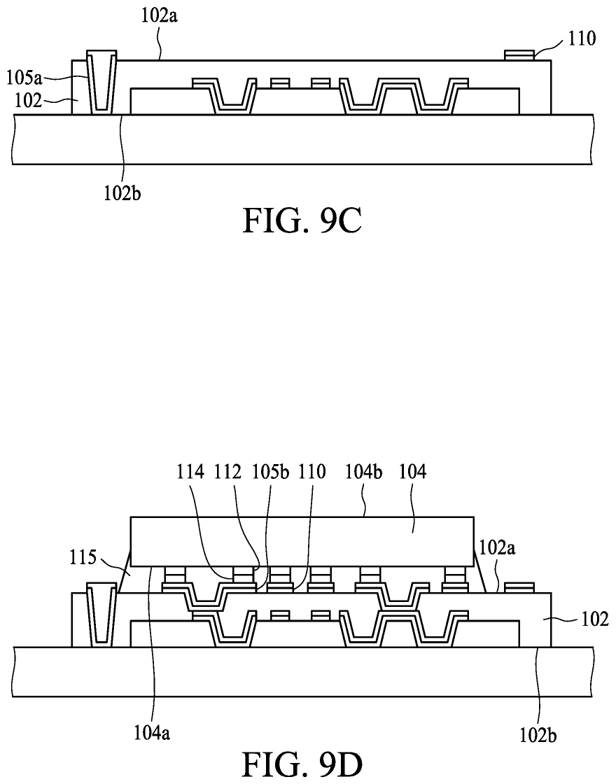

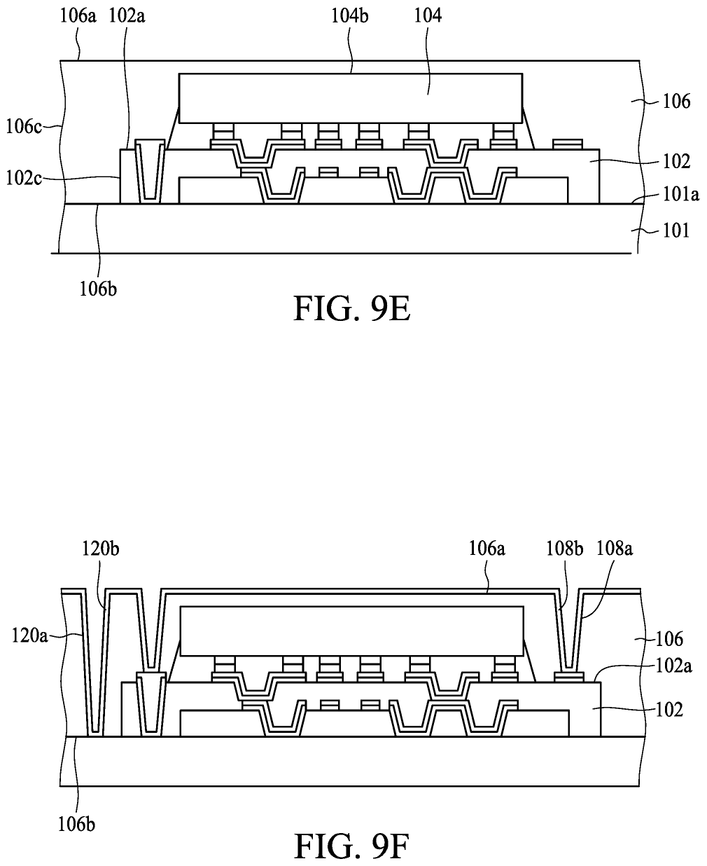

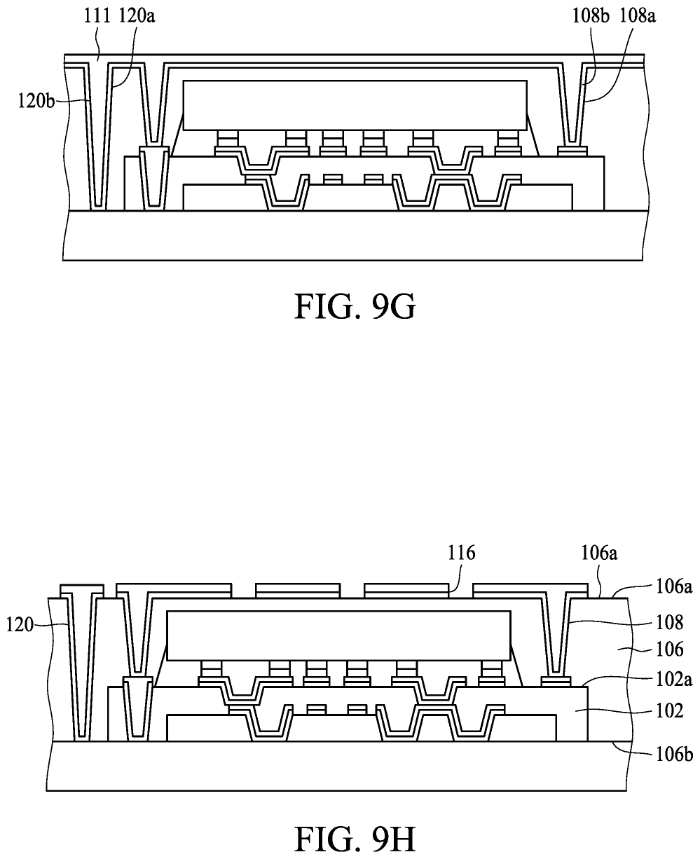

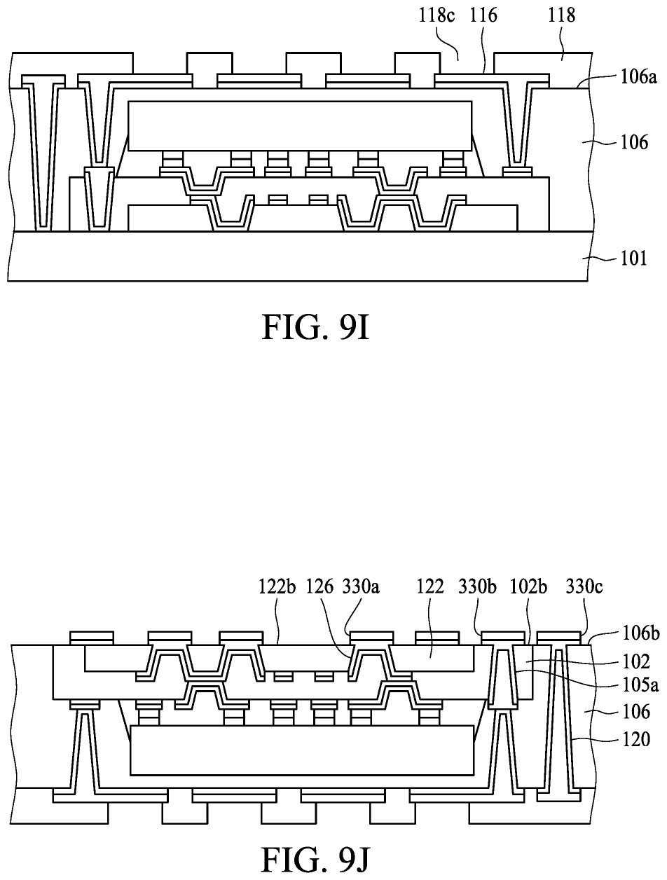

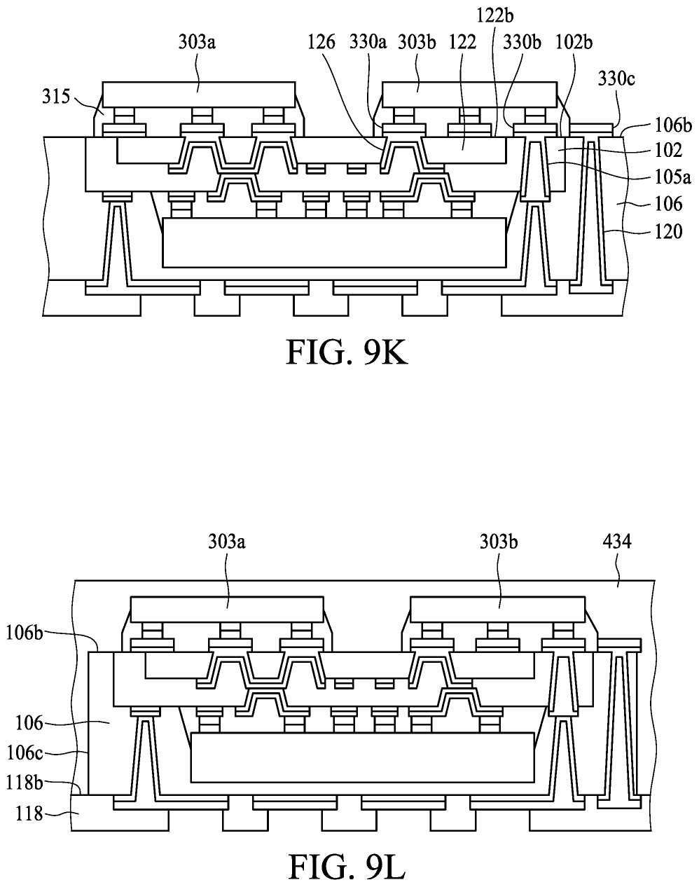

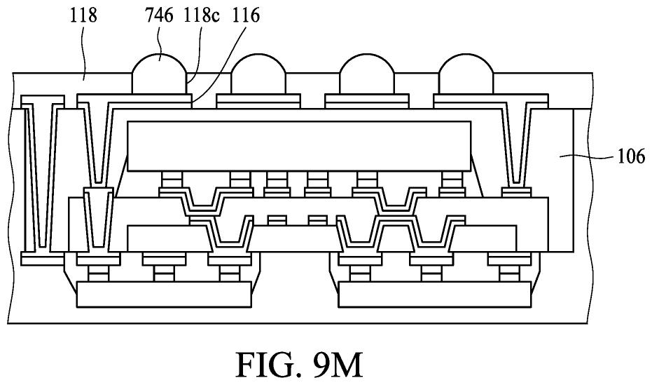

FIGS. 9A-9I illustrate a method for manufacturing a semiconductor package such as the semiconductor package 100 of FIG. 1. FIGS. 9A-9K illustrate a method for manufacturing a semiconductor package such as the semiconductor package 300 of FIG. 3. FIGS. 9A-9L illustrate a method for manufacturing a semiconductor element such as the semiconductor package 400 of FIG. 4. FIGS. 9A-9M illustrate a method for manufacturing a semiconductor package according to an embodiment of the present disclosure.

Referring to FIG. 9A, a carrier 101 is provided. An inner dielectric layer 122 is disposed on a surface 101a of the carrier 101. The inner dielectric layer 122 has an inner top surface 122a, an inner bottom surface 122b opposite to the inner top surface 122a, and an inner side surface 122c extending from the inner top surface 122a to the inner bottom surface 122b. At least one trace layer 124 is disposed adjacent to the inner top surface 122a of the inner dielectric layer 122. At least one inner conductive via 126 is formed extending from the third top surface 122a of the third dielectric layer 122 to the third bottom surface 122b of the third dielectric layer 122. The trace layer 124 and the inner conductive via 126 may be formed by a combination of a physical vapor deposition, plating, photolithography, etching or other suitable processes.

Referring to FIG. 9B, a middle dielectric layer 102 is disposed adjacent to the inner dielectric layer 122 and the surface 101a of the carrier 101. The middle dielectric layer 102 has a middle top surface 102a, a middle bottom surface 102b opposite to the middle top surface 102a, and a middle side surface 102c extending from the middle top surface 102a to the middle bottom surface 102b. The middle dielectric layer 102 covers the inner dielectric layer 122 and the surface 101a of the carrier 101. The middle dielectric layer 102 can be formed by, for example, a lamination technique.

Referring to FIG. 9C, at least one first middle conductive via 105a is disposed extending from the middle top surface 102a of the middle dielectric layer 102 to the middle bottom surface 102b of the middle dielectric layer 102. In addition, at least one middle bonding pad 110 is disposed adjacent to the middle top surface 102a of the middle dielectric layer 102. The middle bonding pad 110 may be, for example, a contact pad of a trace. The middle conductive via 105a and the middle bonding pad 110 may be formed by a combination of a physical vapor deposition, plating, photolithography, etching or other suitable processes.

Referring to FIG. 9D, at least one second middle conductive via 105b is disposed extending from the middle top surface 102a of the middle dielectric layer 102 and ending before the middle bottom surface 102b of the middle dielectric layer 102. The second middle conductive via 105b may be formed by a combination of a physical vapor deposition, plating, photolithography, etching or other suitable processes. A first semiconductor element 104 is disposed adjacent to the middle top surface 102a of the middle dielectric layer 102. The first semiconductor element 104 may be a die, a chip, a package, or an interposer. The first semiconductor element 104 has a first element top surface 104a and a first element bottom surface 104b opposite to the first element top surface 104a. At least one first element bonding pad 112 is disposed adjacent to the first element top surface 104a of the first semiconductor element 104. The first element bonding pad 112 may be, for example, a contact pad of a trace. A first conductive connector 114 is disposed on the first element bonding pad 112. The first semiconductor element 104 may be electrically connected to the middle dielectric layer 102 through bonding the first element bonding pad 112, the first conductive connector 114, and the second middle conductive via 105b. In some embodiments, an underfill 115 is disposed between the middle dielectric layer 102 and the first semiconductor element 104.

Referring to FIG. 9E, a first outer dielectric layer 106 is disposed adjacent to the middle dielectric layer 102 and the surface 101a of the carrier 101. The first outer dielectric layer 106 has a first outer top surface 106a, a first outer bottom surface 106b opposite to the first outer top surface 106a, and a first outer side surface 106c extending from the first outer top surface 106a to the first outer bottom surface 106b. The first outer dielectric layer 106 covers a portion of the middle top surface 102a of the middle dielectric layer 102, at least a portion of the middle side surface 102c of the middle dielectric layer 102, a portion of the first element bottom surface 104b of the first semiconductor element 104, and a portion of the surface 101a of the carrier 101. The first outer dielectric layer 106 can be formed by, for example, a lamination technique.

Referring to FIG. 9F, at least one first outer via 108a is formed extending from the outer top surface 106a of the first outer dielectric layer 106 to the middle top surface 102a of the middle dielectric layer 102. At least one second outer via 120a extending from the first outer bottom surface 106b of the first outer dielectric layer 106 to the first outer top surface 106a of the first outer dielectric layer 106. A metal layer (e.g., a seed layer) 108b, 120b is disposed in the first outer via 108a and the second outer via 120b. The first outer via 108a and the second outer via 120b can be formed by, for example, by a drilling or an etching technique. The metal layer (e.g., a seed layer) 108b, 120b can be formed by, for example, a plating technique.

Referring to FIG. 9G, a conductive layer 111 is disposed adjacent to the metal layer 108b, 120b. The conductive layer 111 may be formed in conformity with the metal layer 108b, 120b. The conductive layer 111 may fill the first outer via 108a and the second outer via 120a. The conductive layer 111 can be formed by, for example, a plating technique.

Referring to FIG. 9H, at least one first outer conductive via 108 is formed extending from the first outer top surface 106a of the first outer dielectric layer 106 to the middle top surface 102a of the middle dielectric layer 102, at least one second outer conductive via 120 is formed extending from the first outer top surface 106a of the first outer dielectric layer 106 to the first outer bottom surface 106b of the first outer dielectric layer 106, and at least one outer bonding pad 116 is disposed adjacent to the first outer top surface 106a of the first outer dielectric layer 106. The first outer conductive via 108, the second outer conductive via 120, and the outer bonding pad 116 may be formed by a combination of a photolithography, etching or other suitable processes.

Referring to FIG. 9I, a protective layer 118 is disposed adjacent to the first outer top surface 106a of the first outer dielectric layer 106. The protective layer 118 defines at least one opening 118c. Each opening 118c corresponds to a respective outer bonding pad 116 and exposes a portion of the outer bonding pad 116. In some embodiments, the protective layer 118 covers a portion of the outer bonding pad 116 and a portion of the first outer top surface 106a of the first outer dielectric layer 106. The opening 118c can be formed by photolithography, etching, laser drilling, or other suitable processes. The protective layer 118 may be disposed by, for example, a coating technique.

Subsequently, the carrier 101 is removed. A semiconductor package (e.g., a semiconductor structure 100 as is illustrated in FIG. 1) can be obtained.

Referring to FIG. 9J, a second inner bonding pad 330a, 330b, 330c is disposed adjacent to the middle bottom surface 102b of the middle dielectric layer 102, the first outer bottom surface 106b of the first outer dielectric layer 106, or the inner bottom surface 122b of the inner dielectric layer 122. The second inner bonding pad 330a, 330b, 330c may electrically connect to the inner conductive via 126 of the inner dielectric layer 102, the first middle conductive via 105a of the middle dielectric layer 102, or the second outer conductive via 120 of the first outer dielectric layer 106. The second inner bonding pad 330a, 330b, 330c may be formed by a combination of a photolithography, etching or other suitable processes.

Referring to FIG. 9K, at least one second semiconductor element 303a, 303b is disposed adjacent to the middle bottom surface 102b of the middle dielectric layer 102, the first outer bottom surface 106b of the first outer dielectric layer 106, or the inner bottom surface 122b of the inner dielectric layer 122. The second semiconductor element 303a, 303b may be a die, a chip, a package, or an interposer. In some embodiments, the second semiconductor element 303a, 303b electrically connects to the second inner bonding pad 330a, 330b, 330c. In some embodiments, the second inner bonding pads 330a, 330b, 330c electrically connect to the inner conductive via 126 of the inner dielectric layer 122, the middle conductive via 105a of the middle dielectric layer 102, and the second outer conductive via 120 of the outer dielectric layer 106, respectively. In some embodiments, an underfill 315 is disposed between the second semiconductor element 303a, 303b and the middle dielectric layer 102, the outer dielectric layer 106, or the inner dielectric layer 122. Subsequently, a semiconductor package (e.g., a semiconductor package 300 as is illustrated in FIG. 3) can be obtained.

Referring to FIG. 9L, a second outer dielectric layer 434 is disposed adjacent to the first outer bottom surface 106b of the first outer dielectric layer 106 after a half cut process to individualize the semiconductor package as is illustrated in FIG. 3 is performed. In some embodiments, the second outer dielectric layer 434 covers a portion of the first outer bottom surface 106b of the first outer dielectric layer 106, at least a portion of the first outer side surface 106c of the first outer dielectric layer 106, a portion of a surface 118b of the protective layer 118, and the second semiconductor element 303a, 303b. The second outer dielectric layer 434 can be formed by, for example, a lamination technique. Subsequently, a singulation process (e.g., sawing) is performed to obtain individual semiconductor package units (e.g., a semiconductor package 400 as is illustrated in FIG. 4). Alternatively, in other embodiments, the second outer dielectric layer 434 may be free from coverage of the first outer side surface 106c of the first outer dielectric layer 106 and a surface 118b of the protective layer 118, if the half cut process was not conducted prior to the formation of the second outer dielectric layer 434.

Referring to FIG. 9M, at least one external electrical connector 746 is disposed adjacent to the opening 118c defined by the protective layer 118. In some embodiments, the external electrical connector 746 electrically connects to the outer bonding pad 116 of the first outer dielectric layer 106. The external electrical connector 746 may be a pillar or a solder/stud bump. The external electrical connector 746 can be formed by, for example, a combination of a plating, soldering, or other suitable processes. Subsequently, a semiconductor package with at least one external connector 746 for external electrical connection can be obtained.

As used herein and not otherwise defined, the terms “substantially” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. As another example, a line or a plane can be substantially flat if a peak or depression of the line or plane is no greater than 5 no greater than 1 or no greater than 0.5 μm.

As used herein, the singular terms “a,” “an,” and “the” may include plural referents unless the context clearly dictates otherwise. In the description of some embodiments, a component provided “on or “over” another component can encompass cases where the former component is directly on (e.g., in physical contact with) the later component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A semiconductor package, comprising:
a first dielectric layer having a first top surface, a first bottom surface opposite to the first top surface, and a first side surface extending from the first top surface to the first bottom surface;
a first semiconductor element disposed adjacent to the first top surface of the first dielectric layer;
a second dielectric layer having a second top surface, a second bottom surface opposite to the second top surface, and a second side surface extending from the second top surface to the second bottom surface, wherein the second dielectric layer covers a top surface of the first semiconductor element and the first side surface of the first dielectric layer; and
at least one first conductive via extending from the first top surface of the first dielectric layer to the second top surface of the second dielectric layer.

2. The semiconductor package of claim 1, wherein the second bottom surface of the second dielectric layer is in substantially the same plane with the first bottom surface of the first dielectric layer.

3. The semiconductor package of claim 1, wherein the second dielectric layer has a projective surface area greater than that of the first dielectric layer.

4. The semiconductor package of claim 1, wherein the first dielectric layer has a first coefficient of thermal expansion (CTE) and the second dielectric layer has a second CTE, wherein the second CTE is greater than the first CTE.

5. The semiconductor package of claim 1, further comprising a third dielectric layer disposed adjacent to the first bottom surface of the first dielectric layer, wherein the third dielectric layer covers the second bottom surface and the second side surface of the second dielectric layer.

6. The semiconductor package of claim 5, wherein the first dielectric layer has a first coefficient of thermal expansion (CTE), the second dielectric layer has a second CTE, and the third dielectric layer has a third CTE, wherein the third CTE is greater than the second CTE and the second CTE is greater than the first CTE.

7. The semiconductor package of claim 5, wherein the third dielectric layer has a projective surface area greater than that of the second dielectric layer and the second dielectric layer has a projective surface area greater than that of the first dielectric layer.

8. The semiconductor package of claim 5, further comprising a second semiconductor element disposed adjacent to the first bottom surface of the first dielectric layer, the third dielectric layer covering a top surface of the second semiconductor element and the second side surface of the second dielectric layer.

9. The semiconductor package of claim 8, further comprising a bonding pad disposed adjacent to the third dielectric layer.

10. The semiconductor package of claim 1, wherein the first dielectric layer comprises fiber.

11. A substrate, comprising:
a first dielectric layer having a first top surface, a first bottom surface opposite to the first top surface, and a first side surface extending from the first top surface to the first bottom surface;
a first semiconductor element disposed adjacent to the first top surface of the first dielectric layer;
a first bonding pad disposed adjacent to the first top surface of the first dielectric layer, the first semiconductor element electrically connected to the first bonding pad;
a second dielectric layer having a second top surface, a second bottom surface opposite to the second top surface, and a second side surface extending from the second top surface to the second bottom surface, wherein the second dielectric layer encapsulates the first semiconductor element and exposes the first bottom surface of the first dielectric layer; and
at least one first conductive via extending from the first top surface of the first dielectric layer to the second top surface of the second dielectric layer.

12. The substrate of claim 11, wherein the second bottom surface of the second dielectric layer is in substantially the same plane with the first bottom surface of the first dielectric layer.

13. The substrate of claim 11, wherein the second dielectric layer has a projective surface area greater than that of the first dielectric layer.

14. The substrate of claim 11, wherein the first dielectric layer has a first coefficient of thermal expansion (CTE) and the second dielectric layer has a second CTE, wherein the second CTE is greater than the first CTE.

15. The substrate of claim 11, further comprising a third dielectric layer disposed adjacent to the second bottom surface of the second dielectric layer, wherein the third dielectric layer covers the second bottom surface and the side surface of the second dielectric layer.

16. The substrate of claim 15, wherein the first dielectric layer has a first coefficient of thermal expansion (CTE), the second dielectric layer has a second CTE, and the third dielectric layer has a third CTE, wherein the third CTE is greater than the second CTE and the second CTE is greater than the first CTE.

17. The substrate of claim 15, wherein the third dielectric layer has a projective surface area greater than that of the second dielectric layer and the second dielectric layer has a projective surface area greater than that of the first dielectric layer.

18. The substrate of claim 15, further comprising a second semiconductor element disposed adjacent to the first bottom surface of the first dielectric layer and covered by the third dielectric layer.

19. The substrate of claim 18, further comprising a second bonding pad disposed adjacent to the third dielectric layer.

20. The substrate of claim 11, wherein the first dielectric layer comprises fiber.

21. (canceled)

22. (canceled)

23. (canceled)

24. (canceled)

25. (canceled)

26. The semiconductor package of claim 1, further comprising at least one second conductive via extending from the second bottom surface of the second dielectric layer to the second top surface of the second dielectric layer.

27. The semiconductor package of claim 5, wherein the first bottom surface of the first dielectric layer and the second bottom surface of the second dielectric layer connects at an interface and the third dielectric layer covers the interface.

28. The semiconductor package of claim 1, further comprising a fourth dielectric layer embedded in the first dielectric layer with a fourth bottom surface exposed from the first bottom surface of the first dielectric layer.

29. The semiconductor package of claim 28, further comprising a third dielectric layer extending from the second side surface of the second dielectric layer to the fourth bottom surface of the fourth dielectric layer.

30. The substrate of claim 15, wherein the first bottom surface of the first dielectric layer and the second bottom surface of the second dielectric layer connects at an interface and the third dielectric layer covers the interface.
